(19) United States
(12) Patent Application Publication
(10) Pub. No.: US 2009/0045739 A1
(43) Pub. Date: Feb. 19, 2009

(54) Organic light emitting diode display device and method of fabricating the same

(76) Inventors: Sam-Il Kho, Suwon-si (KR); Jae-Young Cho, Suwon-si (KR); Sun-Hee Lee, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/222,719

(22) Filed: Aug. 14, 2008

(30) Foreign Application Priority Data
Aug. 16, 2007 (KR) 10-2007-0082355

(51) Int. Cl. H01L 51/52; H01J 9/02

(52) U.S. Cl. 313/504; 445/24

(57) ABSTRACT

An organic light emitting diode (OLED) display device includes a substrate, a first electrode on the substrate, an organic layer on the first electrode, the organic layer including a blue (B) emission layer, a green (G) emission layer, and a red (R) emission layer, the B emission layer including a dopant in an amount of about 10 wt % to about 12 wt %, and a second electrode on the organic layer.

### BACKGROUND OF THE INVENTION

1. Field of the Invention

Embodiments of the present invention relate to an organic light emitting diode (OLED) display device and a method of fabricating the same. In particular, embodiments of the present invention relate to an OLED display device capable of uniformly embodying peaks of red (R), green (G), and blue (B) lights.

2. Description of the Related Art

An OLED display device may include a substrate, an anode on the substrate, an emission layer (EML) on the anode, and a cathode disposed on the EML. Application of voltage between the anode and the cathode may trigger injection of holes and electrons into the EML, so the holes and electrons may recombine to generate excitons. Light may be emitted from the EML, while the excitons transition from an excited state to a ground state.

The OLED display device may include a plurality of EMLs to emit different lights, i.e., red (R), green (G), and/or blue (B) lights, so a full-color OLED display device may be realized. Each of the conventional EMLs emitting R, G, or B lights, however, may exhibit a different luminous efficiency (Cd/A). Thus, the respective R, G, and B EMLs may have different luminance. Accordingly, since luminance of an EML may be proportional to current supplied to the EML, when a substantially same amount of current is applied to the conventional R, G, and B EMLs, the EMLs of the OLED display device may exhibit non-uniform luminance. Thus, it may be difficult to obtain a desired color balance or a white balance in the conventional OLED display device. For example, since the luminous efficiency of a G EML may be three to six times higher than that of an R or B EML, higher current may be required through the R and B EMLs in order to provide a white balance.

Attempts have been made to provide an OLED display device with an EML emitting a single-color light, i.e., white light, with a color filter layer for extracting a predetermined color of light from the EML or with a color conversion layer for converting light emitted by the EML into a predetermined color of light. The conventional OLED display device, however, cannot uniformly implement three peaks of R, G, and B colors because the luminous efficiency of the R EML is substantially lower than that of the B and/or G EMLs. As a result, white light cannot be properly emitted from the conventional OLED display device.

### SUMMARY OF THE INVENTION

Embodiments of the present invention are therefore directed to an OLED display device and a method of fabricating the same, which substantially overcome one or more of the disadvantages and shortcomings of the related art.

It is therefore a feature of an embodiment of the present invention to provide an OLED display with an excessively doped blue emission layer.

It is another feature of an embodiment of the present invention to provide a method of fabricating an OLED display with an excessively doped blue emission layer.

At least one of the above and other features and advantages of the present invention may be realized by providing an OLED display device, including a substrate, a first electrode on the substrate, an organic layer on the first electrode, the organic layer including a blue (B) emission layer, a green (G) emission layer, and a red (R) emission layer, the B emission layer including a dopant in an amount of about 10 wt % to about 12 wt %, and a second electrode on the organic layer. The first electrode may be an anode. The B emission layer may be directly on the first electrode. The G emission layer may be between the B emission layer and the R emission layer. The R emission layer may be between the B emission layer and the G emission layer.

The B emission layer may have a thickness of about 50 angstroms to about 80 angstroms. The B emission layer may include a host material, the host material including amine compounds, triazole derivatives, spiro compounds, anthracene derivatives, and/or biphenyl derivatives. The dopant in the B emission layer may include bis[2-(4,6-difluorophenyl)pyridinato-N,C2′]iridium picolinate (F2Irpic), pyrene derivatives, and/or tris[1-(4,6-difluorophenyl)pyrazolate-N,C2′]iridium(Ir[dfppz]₃). The G emission layer may have a thickness of about 30 angstroms to about 60 angstroms. The R emission layer may have a thickness of about 100 angstroms to about 200 angstroms. The organic layer may include a hole injection layer, a hole transport layer, a hole blocking layer, an electron transport layer, and/or an electron injection layer.

At least one of the above and other features and advantages of the present invention may be realized by providing a method of fabricating an OLED display device, including forming a first electrode on a substrate, forming an organic layer on the first electrode, the organic layer including a blue (B) emission layer, a green (G) emission layer, and a red (R) emission layer, the B emission layer including a dopant in an amount of about 10 wt % to about 12 wt %, and forming a second electrode on the organic layer.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a schematic, cross-sectional view of an OLED display device according to an exemplary embodiment of the present invention;

FIGS. 2-3 illustrate graphs of electroluminescent (EL) spectra of OLED display devices of Examples 1-2, respectively; and

FIGS. 4-5 illustrate graphs of EL spectra of OLED display devices of Comparative Examples 1-2, respectively.

### DETAILED DESCRIPTION OF THE INVENTION

Korean Patent Application No. 10-2007-0082355, filed on Aug. 16, 2007, in the Korean Intellectual Property Office, and entitled: “Organic Light Emitting Diode Display Device and Method of Fabricating the Same,” is incorporated by reference herein in its entirety.

Exemplary embodiments of the present invention will now be described more fully hereinafter with reference to the accompanying drawings, in which exemplary embodiments of the invention are illustrated. Aspects of the invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of elements and regions may be exaggerated for clarity of illustration. It will also be understood that when an element is referred to as being “on” another element or substrate, it can be directly on the other element or substrate, or intervening elements may also be present. Further, it will be understood that the term “on” can indicate solely a vertical arrangement of one element with respect to another element, and may not indicate a vertical orientation, e.g., a horizontal orientation. In addition, it will also be understood that when an element is referred to as being “between” two elements, it can be the only element between the two elements, or one or more intervening elements may also be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of:” For example, the expression “at least one of A, B, and C” may also include an nth member, where n is greater than 3, whereas the expression “at least one selected from the group consisting of A, B, and C” does not.

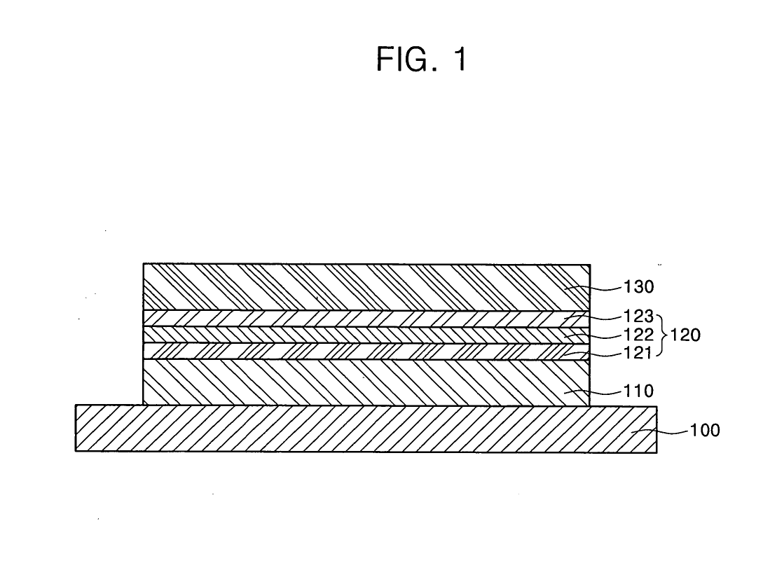

FIG. 1 illustrates a schematic, cross-sectional view of an OLED display device according to an exemplary embodiment of the present invention. Referring to FIG. 1, an OLED display device may include a substrate 100, a first electrode 110 on the substrate 100, a second electrode 130 on the first electrode 110, and an organic layer 120 between the first and second electrodes 110 and 130. The OLED display device may further include a thin film transistor (TFT) (not shown) and a capacitor (not shown) between the substrate 100 and the first electrode 110.

When the OLED display device is a bottom-emitting type, the first electrode 110 may be a transparent conductive layer formed of, e.g., indium tin oxide (ITO), indium zinc oxide (IZO), and/or indium tin zinc oxide (ITZO). When the OLED display device is a top-emitting type, the first electrode 110 may have a double or triple structure that may include a reflective layer. When the first electrode 110 has a double structure, a reflective layer and a transparent conductive layer may be sequentially stacked. The reflective layer may be formed of, e.g., aluminum, silver, and/or an alloy thereof, and the transparent conductive layer may be formed of, e.g., ITO, IZO, and/or ITZO. When the first electrode 110 has a triple structure, first, second, and third metal layers may be sequentially stacked. The first metal layer may be formed of, e.g., titanium, molybdenum, ITO, and/or an alloy thereof, the second metal layer may be formed of, e.g., aluminum, silver, and/or an alloy thereof, and the third metal layer may be formed of, e.g., ITO, IZO, and/or ITZO.

The organic layer 120 of the OLED display device may be formed using, e.g., a vacuum evaporation technique, an inkjet printing technique, and/or a laser-induced thermal imaging (LITI) technique. The organic layer 120 may include a blue (B) emission layer (EML) 121, a red (R) EML 122, and a green (G) EML 123.

The B EML 121 may be formed on the first electrode 110, e.g., directly on the first electrode 110, and may have a thickness of about 50 angstroms to about 80 angstroms, i.e., a thickness providing proper luminous efficiency for obtaining uniform R, G, and B peaks. The B EML 121 may include a blue light emitting host material and a dopant in an amount of about 10 wt % to about 12 wt % of a total weight of the B EML 121.

The amount of about 10 wt % to about 12 wt % of dopant in the B EML 121 may be advantageous in increasing luminous efficiency of a red (R) peak embodied in the R EML 123, thereby facilitating peak uniformity of the B, G, and R EMLs 121, 122, and 123. In particular, the dopant in the B EML 121 may control a carrier balance. Thus, when the B EML 121 includes about 10 wt % to about 12 wt % of dopant, an amount of defects may be increased in the B EML 121, thereby increasing an amount of holes therein. By increasing an energy level having a gap state intermediate between HOMO and LUMO energy levels of the host, transport of charges in the B EML 121 may be facilitated using the energy level having the intermediate gap state, so luminous efficiency may be increased.

For example, when the conventional OLED display device includes a stacked structure of three EMLs in order to embody white light, the luminous efficiency of a peak of an uppermost EML may deteriorate as compared to peaks of the other EMLs. However, when the B EML 121 includes the dopant in an amount of about 10 wt % to about 12 wt %, charges may be transported more smoothly through the B EML 121 toward the upper most EML. Thus, the luminous efficiency of a peak of the uppermost stacked EML, i.e., R or G EML, may be increased. As a result, three peaks of the R, G, and B colors may be uniformly embodied, so that the OLED display device may emit white light.

The blue light emitting host material of the B EML 121 may include, e.g., an amine compound, a triazole derivative, a spiro compound, an anthracene derivative, and/or a biphenyl derivative. More specifically, when the B EML 121 is a phosphorescent material, the host material may include an amine compound, e.g., TMM-004 (COVION Organic Semiconductors, Germany), TAZ, and/or 4,4′-N,N′-dicarbazol-biphenyl (CBP). When the B EML 121 is a fluorescent material, the host material may include an anthracene derivative, e.g., BH232 (Idemitsu Kosan Co., Ltd., Japan) and/or BH215 (Idemitsu Kosan Co., Ltd.).

When the B EML 121 is a phosphorescent material, the dopant may include bis[2-(4,6-difluorophenyl)pyridinato-N,C2′]iridium picolinate (F2Irpic) or tris[1-(4,6-difluorophenyl)pyrazolate-N,C2′]iridium(Ir[dfppz]₃). When the B EML 121 is a fluorescent material, the dopant may include a pyrene derivative, e.g., BD142 (Idemitsu Kosan Co., Ltd.) or BD052 (Idemitsu Kosan Co., Ltd.).

The G EML 122 and R EML 123 may be formed on the B EML 121 in any order. For example, as illustrated in FIG. 1, the G EML 122 may be between the B EML 121 and the R EML 123. The G EML 122 may have a thickness of about 30 angstroms to about 60 angstroms, so the G peak may maintain proper luminous efficiency for obtaining uniform peaks of the R, G, and B, and may be formed of a low molecular material, e.g., CBP(host)/IrPPY(phosphorescent organic complex) or Alq₃(host)/C545t(dopant). The R EML 123 may have a thickness of about 100 angstroms to about 200 angstroms, i.e., so the R peak can easily maintain proper luminous efficiency for obtaining uniform peaks of the R, G, and B, and may be formed of a low molecular material, e.g., Alq₃(host)/DCJTB(fluorescent dopant), Alq₃(host)/DCM(fluorescent dopant), or CBP(host)/PtOEP(phosphorescent organic complex).

The organic layer 120 of the OLED display device may further include at least one of a hole injection layer (HIL), a hole transport layer (HTL), an electron injection layer (EIL), an electron transport layer (ETL), and a hole blocking layer. The hole blocking layer may block transport of holes into the EIL when electron mobility is higher than hole mobility in the organic layer 120. The hole blocking layer may be formed of, e.g., spiro-PBD, 2-(4-biphenyl)-5-(4-butylphenyl)-1,3,4-oxadiazole(PBD), and/or 3-(4-biphenyl)-4-phenyl-5-(4-tert-butylphenyl)-1,2,4-triazole(TAZ).

The HIL may facilitate injection of holes into the organic layer 120 of the OLED display device, and may increase lifetime of the OLED display device. The HIL may be formed of, e.g., an arylamine and/or a starburst amine. Examples of materials for forming the HIL may include phthalocyanine copper (CuPc), 4,4′,4″-tris(3-methylphenylamino)triphenylamine (m-MTDATA), and/or 1,3,5-tris[4-(3-methylphenylamino)phenyl]benzene(m-MTDATB).

The HTL may be formed of an arylene diamine derivative, a starburst compound, a spiro-biphenyl diamine derivative, and/or a ladder compound. Examples of suitable materials for forming the HTL may include N,N-diphenyl-N,N-bis(4-methylphenyl)-1,1-biphenyl-4,4-diamine (TPD) and/or 4,4-bis[N-(1-naphthyl)-N-phenylamine]biphenyl (NPB).

The ETL may be formed of, e.g., an electron-conducting metal compound. Examples of materials for forming the ETL may include tris-(8-hydroxyquinoline) aluminum (Alq₃), which may be highly capable of stably transporting electrons from a cathode. The EIL may be formed of, e.g., 1,3,4-oxadiazole derivatives, LiF, and/or 1,2,4-triazole derivatives.

The second electrode 130 may be formed on the organic layer 120. The second electrode 130 may be formed of a metal having a low work function, e.g., silver (Ag), aluminum (Al), calcium (Ca), magnesium (Mg), and/or an alloy thereof. When the OLED display device is a top-emitting type, the second electrode 130 may be formed of, e.g., a Mg—Ag alloy or an Al—Ag alloy.

### EXAMPLES

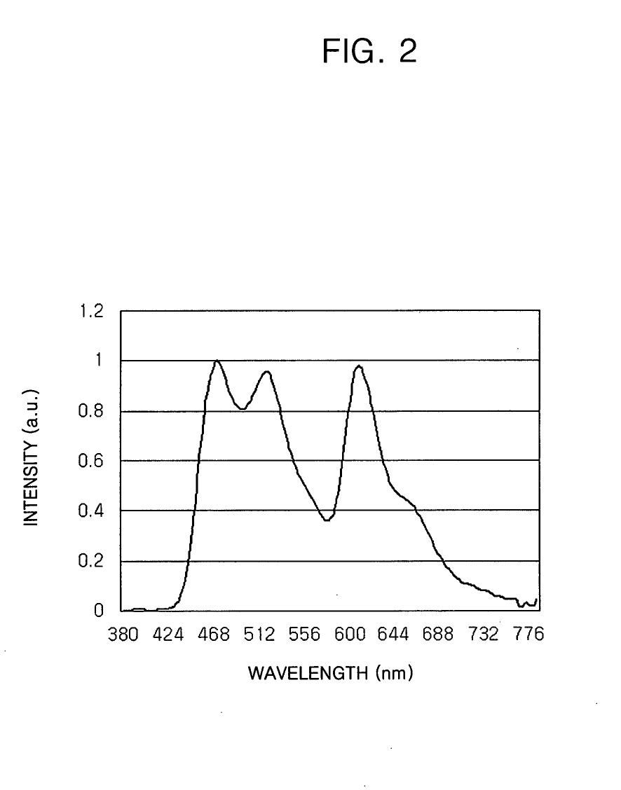

Two OLED display devices were prepared according to embodiments of the present invention, i.e., Examples 1-2, and were compared to two comparative OLED display devices, i.e., Comparative Examples 1-2. The OLED display devices were compared in terms of EL spectra, and in terms of current density, luminous efficiency, and chromaticity coordinates at a luminance of 100 nt. Results are reported in FIGS. 2-5 and Table 1.

### Example 1

An ITO layer was formed on a substrate to a thickness of 70 angstroms. An HIL was formed of IDE406 (Idemitsu Kosan Co., Ltd) on the ITO layer to a thickness of 750 angstroms, and an HTL was formed of IDE320 (Idemitsu Kosan Co., Ltd) on the HIL to a thickness of 150 angstroms. A B EML was formed on the HTL to a thickness of 80 angstroms. The B EML was formed of BH232 (Idemitsu Kosan Co., Ltd) as a host material and 10 wt % of BD142 (Idemitsu Kosan Co., Ltd) as a dopant material. A G EML was formed on the B EML to a thickness of 100 angstroms of CBP (UDC, Co., Ltd.) as a host material and 7 wt % of GGD01 (Gracel Display Inc.) as a dopant material. Also, an R EML was formed on the G EML to a thickness of 120 angstroms of CBP (UDC, Co., Ltd.) as a host material and 12 wt % of RD25 (UDC, Co., Ltd.) as a dopant material. An ETL was formed of LG201 (LG Electronics, Inc.) on the R EML to a thickness of 250 angstroms, and an EIL was formed of LiF on the ETL to a thickness of 5 angstroms. A second electrode was formed of Al on the EIL to a thickness of 2000 angstroms.

### Example 2

An OLED display device was prepared according to the method of Example 1, with the exception of using 12 wt %, instead of 10 wt %, of BD142 as a dopant in the B EML.

### Comparative Example 1

An OLED display device was prepared according to the method of Example 1, with the exception of using 8 wt %, instead of 10 wt %, of BD142 as a dopant in the B EML.

### Comparative Example 2

An OLED display device was prepared according to the method of Example 1, with the exception of using 14 wt %, instead of 10 wt %, of BD142 as a dopant in the B EML.

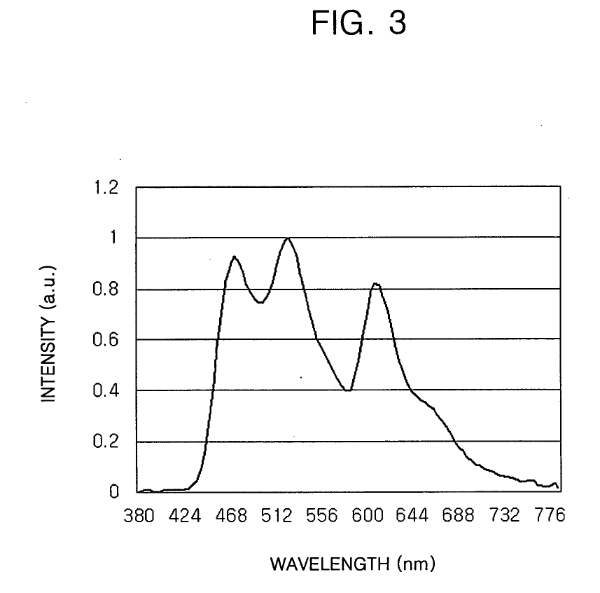

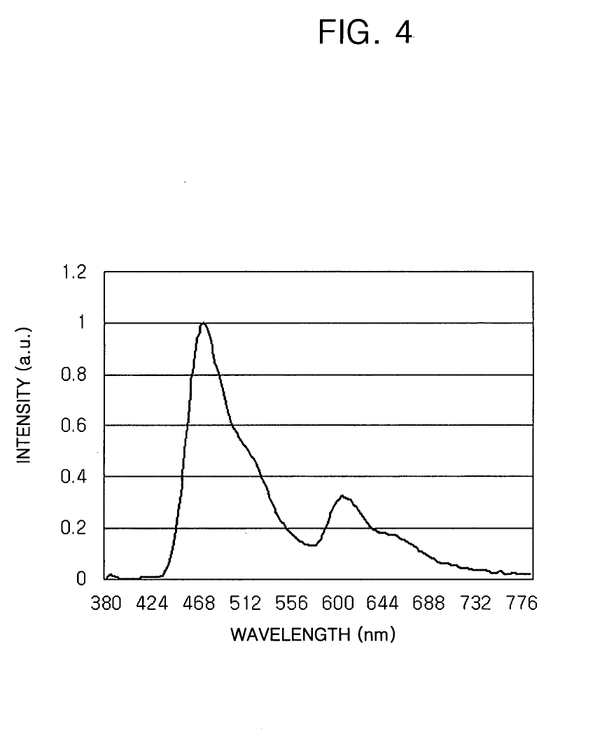

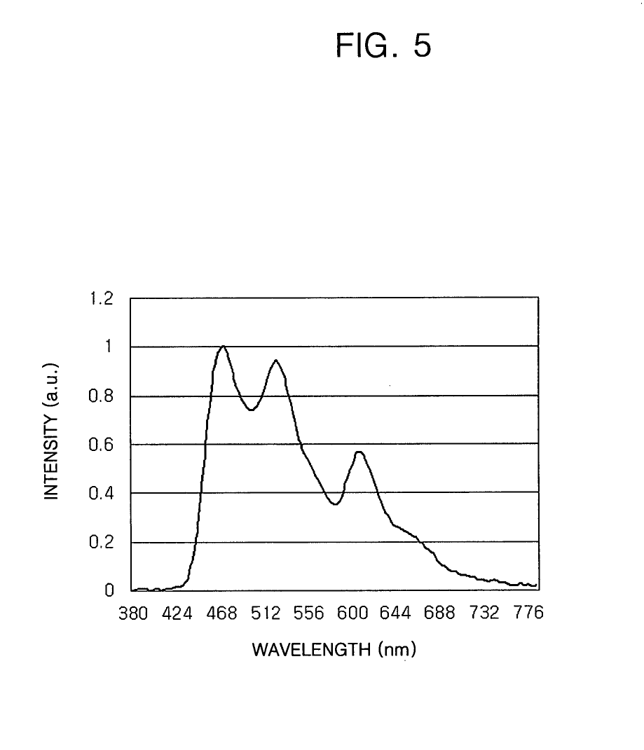

FIGS. 2-3 illustrate graphs of EL spectra of the OLED display devices of Examples 1-2, respectively. FIGS. 4-5 illustrate graphs of EL spectra of the OLED display devices of Comparative Examples 1-2, respectively. In FIGS. 2-5, the x-axis denotes wavelengths in nanometers (nm), and the y-axis denotes intensity in arbitrary units (au).

Referring to FIG. 2, the B EML reached a peak in the wavelength range of 468 nm at an intensity of 1, the G EML reached a peak in the wavelength range of 516 nm at an intensity of 0.95, and the R EML reached a peak in the wavelength range of 604 nm at an intensity of 0.98. As can be seen in FIG. 2, the B, G, and R peaks of the OLED display device of Example 1 were embodied at uniform intensities.

Referring to FIG. 3, the B EML reached a peak in the wavelength range of 468 nm at an intensity of 0.93, the G EML reached a peak in the wavelength range of 520 nm at an intensity of 1, and the R EML reached a peak in the wavelength of 604 nm at an intensity of 0.82. As can be seen in FIG. 3, even though the B, G, and R peaks of the OLED display device of Example 2 were not as uniform as the peaks of Example 1, an intensity variance among the B, G, and R peaks was low, i.e., between 0.07 to 0.18. Accordingly, it can be stated that the B, G, and R peaks were embodied at comparatively uniform intensities.

Referring to FIG. 4, the B EML reached a peak in the wavelength of 468 nm at an intensity of 1, the G EML did not reach a peak, and the R EML reached a peak in the wavelength of 600 nm at an intensity of 0.32. As can be seen in FIG. 4, the OLED display device of Comparative Example 1 did not embody uniform intensities of B, G, and R colors. In particular, while the B peak was embodied and the R peak was embodied at a much lower intensity than the B peak, the G peak was not obtained at all.

Referring to FIG. 5, the B EML reached a peak in the wavelength of 468 nm at an intensity of 1, the G EML reached a peak in the wavelength of 520 nm at an intensity of 0.94, and the R EML reached a peak in the wavelength of 604 nm at an intensity of 0.57. As can be seen in FIG. 4, the OLED display device of Comparative Example 2 did not embody uniform intensities. In particular, although the B and G peaks were embodied at uniform intensities, the R peak was embodied at a much lower intensity than the B and G peaks.

Table 1 shows the driving voltage, current density, luminous efficiency, luminous flux efficiency, and chromaticity coordinates of the OLED display devices of Examples 1-2 and Comparative Examples 1-2 when the luminance of the OLED display devices is 100 nt.

TABLE 1

| | | | | Luminous | | |
|---|---|---|---|---|---|---|
| | Driving | Current | Luminous | flux | x- | y- |
| | voltage | density | efficiency | efficiency | chromaticity | chromaticity |
| | [V] | [mA/cm²] | [Cd/A] | [lm/W] | coordinate | coordinate |
| Example 1 | 5.83 | 8.958 | 12.19 | 6.04 | 0.32 | 0.38 |
| Example 2 | 5.81 | 7.391 | 12.01 | 7.82 | 0.31 | 0.35 |
| Comp. Ex. 1 | 5.83 | 9.581 | 10.45 | 5.65 | 0.26 | 0.29 |
| Comp. Ex. 2 | 5.67 | 7.140 | 11.08 | 7.82 | 0.31 | 0.33 |

As can be seen from Table 1, the OLED display devices of Examples 1-2 and Comparative Examples 1-2 have substantially same driving voltages, and the OLED display device of the First Comparative Example 1 had a higher current density than the OLED display devices of Examples 1-2. As further seen in Table 1, the OLED display devices of Examples 1-2 exhibited superior luminous efficiency as compared to the OLED display devices of Comparative Examples 1-2. It is further noted that even though there was little difference between the chromaticity coordinates of the OLED display devices of Examples 1-2 and the OLED display device of Comparative Example 2, the OLED display devices of Examples 1-2 exhibited better chromaticity coordinates than the OLED display device of Comparative Example 1.

An OLED display device according to embodiments of the present invention may be advantageous in increasing luminous efficiency of a R EML. In particular, a B EML may be excessively doped, so a R peak of the R EML may be increased. Thus, an organic layer including R, G, and B EMLs according to embodiments of the present invention may emit light exhibiting three substantially uniform peaks of R, G, and B colors. In other words, the OLED display device may increase the luminous efficiency of an R peak so that R, G, and B peaks may be uniformly implemented, i.e., have substantially uniform intensities.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims. For example, the present invention may be applied to a double-sided emitting OLED display device.

What is claimed is:

1. An organic light emitting diode (OLED) display device, comprising:
a substrate;
a first electrode on the substrate;
an organic layer on the first electrode, the organic layer including a blue (B) emission layer, a green (G) emission layer, and a red (R) emission layer, the B emission layer including a dopant in an amount of about 10 wt % to about 12 wt %; and
a second electrode on the organic layer.

2. The OLED display device as claimed in claim 1, wherein the first electrode is an anode.

3. The OLED display device as claimed in claim 1, wherein the B emission layer is directly on the first electrode.

4. The OLED display device as claimed in claim 3, wherein the G emission layer is between the B emission layer and the R emission layer.

5. The OLED display device as claimed in claim 3, wherein the R emission layer is between the B emission layer and the G emission layer.

6. The OLED display device as claimed in claim 1, wherein the B emission layer has a thickness of about 50 angstroms to about 80 angstroms.

7. The OLED display device as claimed in claim 1, wherein the B emission layer includes a host material, the host material including amine compounds, triazole derivatives, spiro compounds, anthracene derivatives, and/or biphenyl derivatives.

8. The OLED display device as claimed in claim 1, wherein the dopant in the B emission layer includes bis[2-(4,6-difluorophenyl)pyridinato-N,C2′]iridium picolinate (F2Irpic), pyrene derivatives, and/or tris[1-(4,6-difluorophenyl)pyrazolate-N,C2′]iridium(Ir[dfppz]3).

9. The OLED display device as claimed in claim 1, wherein the G emission layer has a thickness of about 30 angstroms to about 60 angstroms.

10. The OLED display device as claimed in claim 1, wherein the R emission layer has a thickness of about 100 angstroms to about 200 angstroms.

11. The OLED display device as claimed in claim 1, wherein the organic layer includes a hole injection layer, a hole transport layer, a hole blocking layer, an electron transport layer, and/or an electron injection layer.

12. A method of fabricating an organic light emitting diode (OLED) display device, comprising:
forming a first electrode on a substrate;
forming an organic layer on the first electrode, the organic layer including a blue (B) emission layer, a green (G) emission layer, and a red (R) emission layer, the B emission layer including a dopant in an amount of about 10 wt % to about 12 wt %; and
forming a second electrode on the organic layer.
